(19) United States
(12) Patent Application Publication
(10) Pub. No.: US 2026/0255927 A1
(43) Pub. Date: Aug. 27, 2026

(54) SEMICONDUCTOR PRODUCTION APPARATUS AND INSTALLATION METHOD

(71) Applicant: Tokyo Electron Limited, Tokyo (JP)

(72) Inventors: Yusuke HAYASAKA, Miyagi (JP); Kazuya MATSUMOTO, Miyagi (JP)

(73) Assignee: Tokyo Electron Limited, Tokyo (JP)

(21) Appl. No.: 19/651,841

(22) Filed: Apr. 20, 2026

Related U.S. Application Data
(63) Continuation of application No. PCT/JP2024/038678, filed on Oct. 30, 2024.

(30) Foreign Application Priority Data
Nov. 1, 2023 (JP) 2023-187933

(51) Int. Cl. H10P 72/76

(52) U.S. Cl. CPC H10P 72/7612

(57) ABSTRACT

A semiconductor production apparatus is a semiconductor production apparatus for producing a semiconductor, and includes an accommodated object installed inside an apparatus frame of the semiconductor production apparatus, and a holding member accommodated inside the apparatus frame together with the accommodated object and for holding the accommodated object. The holding member includes a base body, an attachment body attached to a lower portion of the accommodated object, and a lifting structure provided between the base body and the attachment body and for lifting the attachment body from the base body.

### CROSS-REFERENCE TO RELATED APPLICATIONS

This application is a bypass continuation application of international application No. PCT/JP2024/038678 having an international filing date of Oct. 30, 2024 and designating the United States, the international application being based upon and claiming the benefit of priority from Japanese Patent Application No. 2023-187933 filed on Nov. 1, 2023, the entire contents of each are incorporated herein by reference.

### TECHNICAL FIELD

The present disclosure relates to a semiconductor production apparatus and an installation method.

### BACKGROUND

PTL 1 discloses a semiconductor production apparatus including a plurality of multi-chamber type process modules. In the semiconductor production apparatus, a gas box for supplying a gas to processing modules and an electrical box for supplying power are accommodated in an accommodation space on a lower side of each processing module. Further, the gas box and the electrical box each include a caster at a lower portion thereof, and can be pulled out to the outside of the processing module.

### CITATION LIST

### Patent Documents

PTL 1: U.S. Pat. No. 9,312,155

### SUMMARY

The present disclosure provides a technique that can easily install an accommodated object of a semiconductor production apparatus.

According to an aspect of the present disclosure, provided is a semiconductor production apparatus for producing a semiconductor, the semiconductor production apparatus including: an accommodated object installed inside an apparatus frame of the semiconductor production apparatus; and a holding member accommodated inside the apparatus frame together with the accommodated object and configured to hold the accommodated object, in which the holding member includes a base body, an attachment body attached to a lower portion of the accommodated object, and a lifting structure provided between the base body and the attachment body to lift the attachment body from the base body.

According to one aspect, an accommodated object of a semiconductor production apparatus can be easily installed.

### BRIEF DESCRIPTION OF DRAWINGS

FIG. 1 schematically illustrates a plasma processing system according to an embodiment.

FIG. 2A is a schematic side view illustrating a state where a power source of the plasma processing apparatus is accommodated in an apparatus frame. FIG. 2B is a perspective view illustrating a state of a process of installing the power source.

FIG. 3 is a perspective view illustrating a holding member.

FIG. 4 is an exploded perspective view of the holding member in FIG. 3 according to the embodiment.

FIG. 5 is a perspective view illustrating a state where a power source housing is held by the holding member.

FIGS. 6A and 6B are side views illustrating an example of adjustment of a height position of the holding member.

FIG. 7A is a flowchart illustrating a procedure of an installation method for installing the power source housing to the apparatus frame. FIG. 7B is a flowchart illustrating a procedure of a removing method for removing the power source housing from the apparatus frame.

FIG. 8A is a first perspective view illustrating a process when a power source housing 60 is installed. FIG. 8B is a second perspective view illustrating a process subsequent to FIG. 8A. FIG. 8C is a third perspective view illustrating a process subsequent to FIG. 8B.

### DETAILED DESCRIPTION

Hereinafter, embodiments for implementing the present disclosure will be described with reference to the drawings. In the respective drawings, the same components will be denoted by the same reference numerals, and overlapping descriptions thereof may be appropriately omitted.

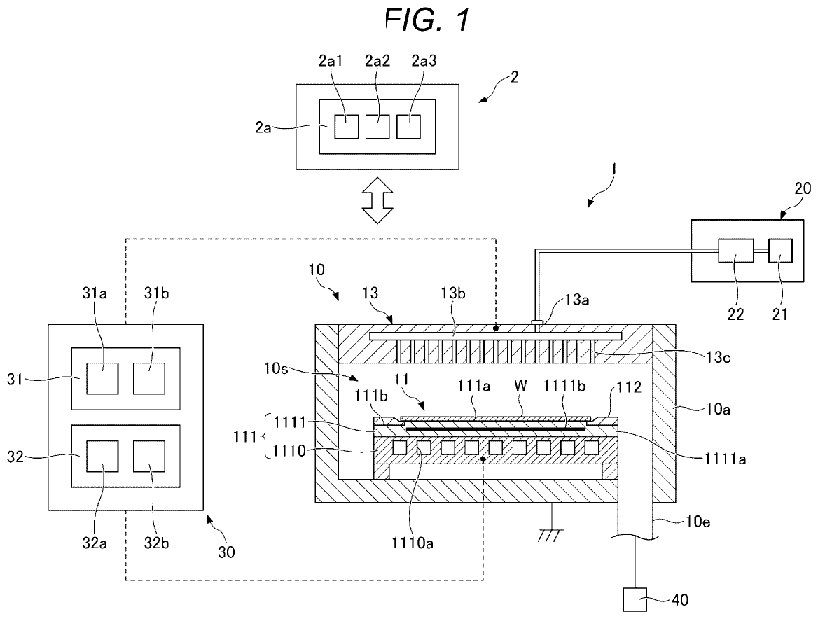

First, a plasma processing system including a capacitively coupled plasma processing apparatus 1 that is an example of a semiconductor production apparatus according to an embodiment will be described with reference to FIG. 1. FIG. 1 schematically illustrates the plasma processing system according to the embodiment.

The plasma processing system includes a capacitively coupled plasma processing apparatus 1 and a controller 2. The capacitively coupled plasma processing apparatus 1 includes a plasma processing chamber 10, a gas supply 20, a power source 30, and an exhaust system 40. Further, the plasma processing apparatus 1 includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a portion of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 has at least one gas supply port for supplying at least one processing gas into the plasma processing space 10s, and at least one gas exhaust port for exhausting the gas from the plasma processing space. The sidewall 10a is grounded. The shower head 13 and the substrate support 11 are electrically insulated from a housing of the plasma processing chamber 10.

The substrate support 11 includes a main body 111 and a ring assembly 112. The main body 111 has a central region (substrate support surface) 111a for supporting a substrate (wafer) W, and an annular region (ring support surface) 111b for supporting the ring assembly 112. The annular region 111b of the main body 111 surrounds the central region 111a of the main body 111 in a plan view. The substrate W is disposed on the central region 111a of the main body 111 and the ring assembly 112 is disposed on the annular region 111b of the main body 111 to surround the substrate W on the central region 111a of the main body 111. In one embodiment, the main body 111 includes a base and an electrostatic chuck. The base includes a conductive member. The conductive member of the base functions as a lower electrode. The electrostatic chuck is disposed on the base. An upper surface of the electrostatic chuck has a substrate support surface 111a. The ring assembly 112 includes one or more annular members. At least one of the one or more annular members is an edge ring. Although not illustrated, the substrate support 11 may include a temperature control module configured to adjust at least one of the electrostatic chuck, the ring assembly 112, and the substrate to a target temperature. The temperature control module may include a heater, a heat transfer medium, a flow path, or a combination thereof. A heat transfer fluid, such as brine or gas, flows through the flow path. Further, the substrate support 11 may include a heat transfer gas supply configured to supply a heat transfer gas between the rear surface of the substrate W and the substrate support surface 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the gas introduction ports 13c. Further, the shower head 13 includes a conductive member. The conductive member of the shower head 13 functions as an upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include one or more flow rate modulation devices that modulate or pulse flow rates of at least one processing gas.

The power source 30 includes an RF power source 31 coupled to plasma processing chamber 10 via at least one impedance matching circuit. The RF power source 31 is configured to supply at least one RF signal (RF power), such as a source RF signal and a bias RF signal, to the conductive member of the substrate support 11 and/or the conductive member of the shower head 13. As a result, plasma is formed from at least one processing gas supplied into the plasma processing space 10s. Accordingly, the RF power source 31 may function as at least a portion of a plasma generator configured to generate plasma from one or more processing gases in the plasma processing chamber 10. Further, supplying of the bias RF signal to the conductive member of the substrate support 11 can generate a bias potential in the substrate W to draw an ion component in the formed plasma to the substrate W.

In one embodiment, the RF power source 31 includes a first RF generator 31a and a second RF generator 31b. The first RF generator 31a is coupled to the conductive member of the substrate support 11 and/or the conductive member of the shower head 13 via at least one impedance matching circuit, and configured to generate a source RF signal (source RF power) for plasma generation. In one embodiment, the source RF signal has a frequency in the range of 13 MHz to 150 MHz. In one embodiment, the first RF generator 31a may be configured to generate a plurality of source RF signals having different frequencies. The generated one or a plurality of source RF signals are supplied to the conductive member of the substrate support 11 and/or the conductive member of the shower head 13. The second RF generator 31b is coupled to the conductive member of the substrate support 11 via at least one impedance matching circuit, and configured to generate a bias RF signal (bias RF power). In one embodiment, the bias RF signal has a lower frequency than the source RF signal. In one embodiment, the bias RF signal has a frequency in the range of 400 kHz to 13.56 MHz. In one embodiment, the second RF generator 31b may be configured to generate a plurality of bias RF signals having different frequencies. The generated one or more bias RF signals are supplied to the conductive member of the substrate support 11. Further, in various embodiments, at least one of the source RF signal and the bias RF signal may be pulsed.

Further, the power source 30 may include a DC power source 32 coupled to the plasma processing chamber 10. The DC power source 32 includes a first DC generator 32a and a second DC generator 32b. In one embodiment, the first DC generator 32a is connected to the conductive member of the substrate support 11 and configured to generate a first DC signal. The generated first DC signal is applied to the conductive member of the substrate support 11. In one embodiment, the first DC signal may be applied to another electrode, such as an electrode in an electrostatic chuck. In one embodiment, the second DC generator 32b is configured to be connected to the conductive member of the shower head 13 and to generate a second DC signal. The generated second DC signal is applied to the conductive member of the shower head 13. In various embodiments, at least one of the first and second DC signals may be pulsed. The first and second DC generators 32a and 32b may be provided in addition to the RF power source 31, and the first DC generator 32a may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure adjusting valve adjusts a pressure in the plasma processing space 10s. The vacuum pump may include a turbo molecular pump, a dry pump, or a combination thereof.

The controller 2 processes computer-executable instructions for instructing the plasma processing apparatus 1 to execute various steps described herein below. The controller 2 may be configured to control elements of the plasma processing apparatus 1 to execute the various steps described herein below. In one embodiment, part or all of the controller 2 may be in the plasma processing apparatus 1. The controller 2 may include, for example, a computer 2a. For example, the computer 2a may include a processor (central processing unit (CPU)) 2a1, a storage 2a2, and a communication interface 2a3. The processor 2a1 may be configured to perform various control operations based on a program stored in the storage 2a2. The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

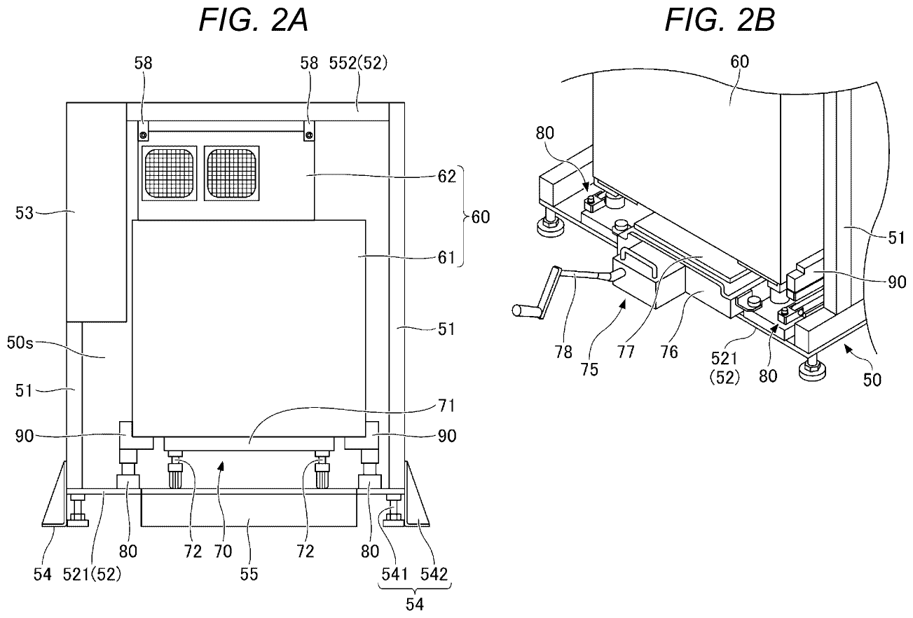

FIG. 2A is a schematic side view illustrating a state where the power source 30 of the plasma processing apparatus 1 is accommodated in an apparatus frame 50. FIG. 2B is a perspective view illustrating a state of a process of installing the power source 30. As illustrated in FIG. 2A, the plasma processing apparatus 1 is assembled as an integrated unit by installing the power source 30 below the apparatus frame 50 that accommodates the plasma processing chamber 10 (see FIG. 1). The apparatus frame 50 defines an installation range in a width direction of the plasma processing apparatus 1 by accommodating each configuration of the plasma processing apparatus 1 on an inner side in a vertical direction. Accordingly, a multi-chamber type substrate processing system including a plurality of plasma processing apparatuses 1 can be installed without bringing the plasma processing apparatuses 1 into contact with each other.

The apparatus frame 50 according to the embodiment is formed by assembling a pair of side frames 51 extending in the vertical direction and a plurality of bridging frames 52 that bridge between the pair of side frames 51 in a horizontal direction. For each side frame 51 and each bridging frame 52, members such as square tubular bars and panels can be used. By fixing each side frame 51 and each bridging frame 52 to each other using a fixing method such as screw-fastening or welding, the apparatus frame 50 can firmly support each configuration of the plasma processing apparatus 1 on the inner side thereof. A space of the apparatus frame 50 below the plasma processing chamber 10 and surrounded by the pair of side frames 51 and upper and lower bridging frames 52 serves as an accommodation space 50s for accommodating a power source housing 60 of the power source 30.

The power source housing 60 is a housing that accommodates part or all of the power source 30 described above. For example, the power source housing 60 accommodates the RF power source 31 (see FIG. 1) and the DC power source 32 (see FIG. 1) that supply power to the substrate support 11 of the plasma processing chamber 10. In addition, the power source housing 60 may accommodate a power source that supplies power to each configuration of the plasma processing apparatus 1 (such as a power source that supplies power to the electrostatic chuck or the temperature control module). Another portion of the power source 30 that supplies power to the shower head 13 of the plasma processing chamber 10 may be disposed above the plasma processing chamber 10.

The power source housing 60 includes a main housing 61 that accommodates the RF power source 31 and the DC power source 32, and a sub-housing 62 that accommodates the impedance matching circuit. The impedance matching circuit matches an impedance of a load side (substrate support 11 side) of the RF power source 31 with an output impedance of the RF power source 31. The sub-housing 62 is smaller than the main housing 61, and is fixed, for example, on a top plate of the main housing 61.

For example, a size (such as a width, a depth, and a height) of the power source housing 60 changes according to performance such as a maximum voltage supplied by the power source 30. Therefore, the accommodation space 50s of the apparatus frame 50 accommodating the power source housing 60 has a size somewhat larger than the accommodated power source housing 60.

As described above, the apparatus frame 50 forms the accommodation space 50s for accommodating the power source housing 60 by the pair of side frames 51 and the two, upper and lower, bridging frames 52. Hereinafter, the lower bridging frame 52 will be referred to as a bottom frame 521, and the upper bridging frame 52 will be referred to as an intermediate frame 522. In addition, a control box 53 accommodating a control substrate for controlling the power source 30 is installed at one of the pair of side frames 51.

A plurality of fixing structures 54 for fixing the apparatus frame 50 to a floor are provided at the bottom frame 521 and lower portions of the pair of side frames 51. Each fixing structure 54 includes a level adjuster 541 and a fixing jig 542 fixed to a side of the level adjuster 541. Each level adjuster 541 is attached to a lower portion of the bottom frame 521 and has an adjustable height. By adjusting the height of each level adjuster 541, each bridging frame 52 including the bottom frame 521 is installed to be parallel to the horizontal direction. Each fixing jig 542 is formed in a right triangular shape and connected to the pair of side frames 51 of the apparatus frame 50 whose height is adjusted by each level adjuster 541, and thus supports an upright posture of the apparatus frame 50.

As illustrated in FIGS. 2A and 2B, when the power source housing 60 is installed in the accommodation space 50s, a cart 70 and an elevation jig 75 are used. That is, an operator mounts the power source housing 60 at the cart 70, and inserts the power source housing 60 into the accommodation space 50s by moving the power source housing 60 and the cart 70. FIG. 2A illustrates the power source housing 60 in a state of being mounted at the cart 70. Thereafter, the operator inserts the elevation jig 75 illustrated in FIG. 2B between an upper surface of the bottom frame 521 and a lower surface of the cart 70 to lift the power source housing 60 and the cart 70 by the elevation jig 75. Further, the operator inserts a pair of holding members 80 in the state where the power source housing 60 is lifted, and holds the power source housing 60 by the holding members 80. In addition, after the power source housing 60 is held by the holding members 80, the elevation jig 75 is removed from the apparatus frame 50. The cart 70 may be integrated with the power source housing 60, or may be detached from the power source housing 60 and removed from the apparatus frame 50.

The cart 70 includes a flat panel stage 71 and a plurality of casters 72 that are attached to a lower portion of the panel stage 71. In addition, an inclined frame 55 where the cart 70 mounted with the power source housing 60 is movable is assembled to an opening side of the accommodation space 50s of the bottom frame 521. The inclined frame 55 may be attached to the bottom frame 521 and separated after accommodating when the power source housing 60 is accommodated in the accommodation space 50s using the cart 70.

The elevation jig 75 includes a main body 76, a stage 77 in direct contact with the power source housing 60 above the main body 76, and a handle 78 that protrudes from the main body 76. The main body 76 includes therein an elevation mechanism (not illustrated) that lifts the stage 77 based on rotation of the handle 78 in a first direction and lowers the stage 77 based on rotation of the handle 78 in a second direction.

A height of the accommodation space 50s in the vertical direction is higher than an overall height of the power source housing 60 where the main housing 61 and the sub-housing 62 are overlapped. Therefore, the plasma processing apparatus 1 is configured to maintain, by the pair of holding members 80, a height position of the power source housing 60 by sliding and inserting the pair of holding members 80 relatively to the power source housing 60. In the accommodation space 50s, the power source housing 60 is stably held by the pair of holding members 80, and the elevation jig 75 and the cart 70 can be smoothly detached from the power source housing 60.

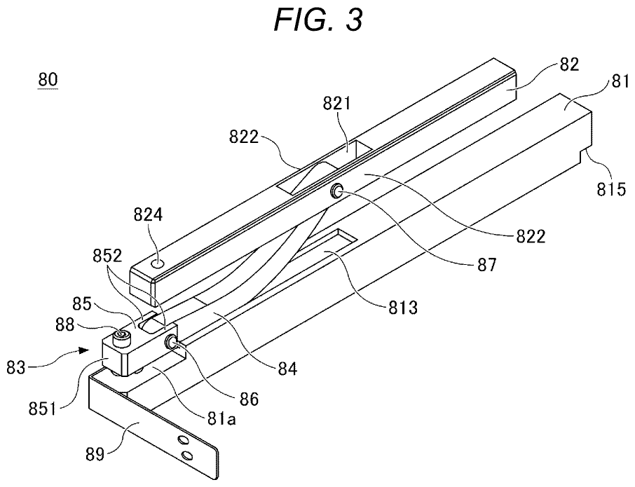

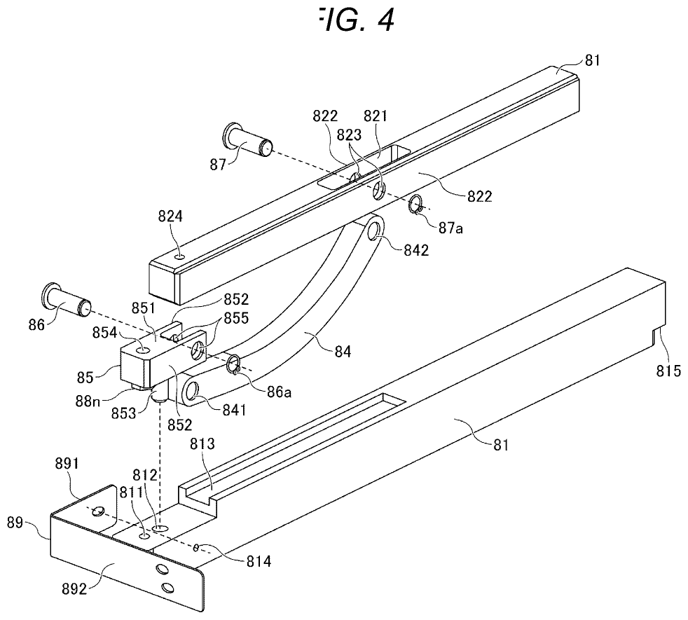

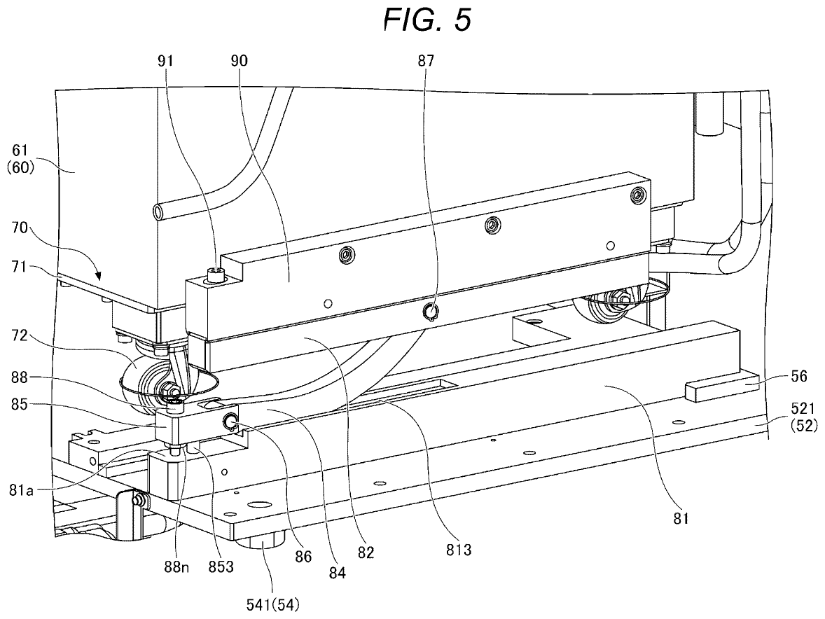

FIG. 3 is a perspective view illustrating each holding member 80 according to the embodiment. FIG. 4 is an exploded perspective view of the holding member 80 in FIG. 3. As shown in FIGS. 3 and 4, the pair of holding members 80 are long jigs that are inserted from an opening of the accommodation space 50s (see FIG. 2B) in a depth direction of the apparatus frame 50 by assembling a plurality of components. Specifically, each holding member 80 includes a base body 81 provided below, an attachment body 82 attached to the power source housing 60 above the base body 81, and a lifting structure 83 provided between the base body 81 and the attachment body 82 to lift the attachment body 82 from the base body 81. The attachment body 82 according to the embodiment is attached to the power source housing 60 through a lower jig 90 (see FIG. 5) to be described later, and alternatively, the plasma processing apparatus 1 may be configured such that the attachment body 82 is directly attached to the power source housing 60.

The base body 81 is formed in a square tubular shape thicker than the attachment body 82 and the lifting structure 83, and extends linearly. A length of the base body 81 in an extending direction (longitudinal direction) is set to be slightly shorter than a length of the accommodation space 50s in the depth direction.

A screw hole 811 and an engaging hole 812 for attaching the lifting structure 83 are formed at one end of an upper surface of the base body 81. In addition, the one end of the base body 81 having the screw hole 811 and the engaging hole 812 forms a stepped surface 81a lower than other portions. Further, a guide groove 813 for guiding the lifting structure 83 is formed at a position adjacent to the stepped surface 81a on the upper surface of the base body 81. The guide groove 813 extends from the stepped surface 81a to an intermediate position in the extending direction of the base body 81.

A connection component 89 for connecting the holding member 80 to each side frame 51 (see FIG. 2B) of the apparatus frame 50 is attached to the one end of the base body 81. The connection component 89 is formed in an L-shape obtained by bending a long plate. The connection component 89 includes a base body side connection portion 891 connected to the base body 81, and a frame side connection portion 892 orthogonally continuous with the base body side connection portion 891 and connected to the side frames 51 while extending in a width direction of the base body 81.

A screw hole 814 for screw-fastening the base body side connection portion 891 of the connection component 89 is formed through a pair of left and right side surfaces of the base body 81 at the one end. For example, the connection component 89 screw-fastens the base body side connection portion 891 to a left side surface of the base body 81, and causes the frame side connection portion 892 to protrude to a right side of the base body 81 (see FIG. 3). Accordingly, the frame side connection portion 892 can be connected (screw-fastened) to the right side frame 51. Conversely, the connection component 89 screw-fastens the base body side connection portion 891 to a right side surface of the base body 81, and causes the frame side connection portion 892 to protrude to a left side of the base body 81. Accordingly, the frame side connection portion 892 can be connected (screw-fastened) to the left side frame 51.

The base body 81 includes a positioning portion 815 for positioning the base body 81 in a depth direction when accommodating the holding member 80 in the accommodation space 50s, at the other end opposite to the one end. The positioning portion 815 according to the embodiment is formed by cutting away a corner portion between the other end surface and a lower surface of the base body 81.

Meanwhile, the attachment body 82 is formed in a square tubular shape and extends linearly, similarly to the base body 81. A length of the attachment body 82 in an extending direction (longitudinal direction) is shorter than the length of the base body 81 in the extending direction. For example, the length of the attachment body 82 in the extending direction coincides with a length of the lower jig 90 attached to a lower portion of the power source housing 60 in an extending direction (see FIG. 5). One end of the attachment body 82 has a screw hole 824 for screw-fastening to the lower jig 90.

A through-hole 821 extending through an upper-lower direction is formed in a predetermined range in the middle of the attachment body 82. The other end of a support 84 of the lifting structure 83 is inserted into the through-hole 821. A pair of left and right extending plates 822 extend in the longitudinal direction at a location where the through-hole 821 is formed in the attachment body 82. Each extending plate 822 is formed with a connection hole 823 for connecting with the support 84 of the lifting structure 83. A pair of left and right connection holes 823 are located exactly at an intermediate position in the extending direction of the attachment body 82.

The lifting structure 83 is a structure provided between the base body 81 and the attachment body 82. The lifting structure 83 includes the support 84 and a height adjustment member 85 (e.g., height adjuster) connected to one end of the support 84 and connected to the base body 81. In addition, the lifting structure 83 includes a connection pin 86 that connects the support 84 and the height adjustment member 85, and a connection pin 87 that connects the support 84 and the attachment body 82.

The support 84 is formed in a square tubular shape that is slightly thinner than the attachment body 82, and extends in a curved manner in an arc shape along the longitudinal direction. A pin hole 841 extending through a left-right direction is formed at one end side of the support 84. In addition, a pin hole 842 extending through the left-right direction is formed at the other end side of the support 84.

The other end of the support 84 is inserted into the through-hole 821 of the attachment body 82, and is connected to the attachment body 82 by inserting the connection pin 87 in a state where the connection hole 823 of the attachment body 82 and the pin hole 842 overlap each other. The connection pin 87 is prevented from being detached by a retaining component 87a. The attachment body 82 is rotatably connected to the support 84 (in a free state), and an angle between the attachment body 82 and the support 84 can be freely changed.

Meanwhile, the height adjustment member 85 is formed in a U-shape that can sandwich the support 84 in a plan view. Specifically, the height adjustment member 85 includes a block-shaped base portion 851, a pair of protruding pieces 852 that protrude a short distance from the base portion 851 in the other end direction, and an engaging pin 853 that protrudes downward from a lower surface of the base portion 851. In addition, the height adjustment member 85 includes a height adjustment screw 88 (see FIG. 5), and this height adjustment screw 88 is inserted into an insertion hole 854 of one end of the base portion 851 (opposite from each protruding piece 852 (a connection location connected to the support 84) with the engaging pin 853 interposed therebetween).

The pair of protruding pieces 852 of the height adjustment member 85 accommodate the one end of the support 84 therebetween. A connection hole 855 is formed through each of the pair of protruding pieces 852. The one end of the support 84 is inserted between the pair of protruding pieces 852 of the height adjustment member 85 and is connected to the height adjustment member 85 by inserting the connection pin 86 in a state where each connection hole 855 and the pin hole 841 overlap each other. The connection pin 86 is prevented from being detached by the retaining component 86a. The height adjustment member 85 and the support 84 are rotatably connected to each other (in a free state).

The engaging pin 853 of the height adjustment member 85 is inserted into the engaging hole 812 of the base body 81 and engages with the base body 81. The engaging pin 853 is slightly thicker than the engaging hole 812, and along with height adjustment of the height adjustment member 85, a distance between the height adjustment member 85 and the base body 81 is changed and a height thereof is maintained.

FIG. 5 is a perspective view illustrating a state where the power source housing 60 is held by the holding member 80. As shown in FIG. 5, the holding member 80 adjusts a height of the attachment body 82 via the support 84 by inserting the height adjustment screw 88 into the insertion hole 854 and screw-fastening into the screw hole 811 (see FIG. 4) of the base body 81 when the power source housing 60 is held. A height of the height adjustment screw 88 can be changed in the vertical direction by adjusting a degree of threading engagement with respect to a nut 88n or the screw hole 811. Therefore, the height adjustment member 85 can adjust a height of the one end of the support 84 based on the degree of threading engagement of the height adjustment screw 88.

The support 84 is supported in the guide groove 813 of the base body 81 at an intermediate position between the one end connected to the height adjustment member 85 and the other end connected to the attachment body 82. More specifically, a lower surface near the one end of the support 84 comes into contact with a bottom surface of the guide groove 813, and the other end of the support 84 extends obliquely upward along with curvature of the support 84 from such a contact portion to support the attachment body 82. The contact portion of the support 84 serves as a fulcrum for supporting the attachment body 82 and the power source housing 60.

In other words, the lifting structure 83 supports the attachment body 82 based on a leverage principle in which the contact portion of the support 84 serves as a fulcrum, the one end (a portion connected with the height adjustment member 85) of the support 84 serves as an effort point, and the other end (a portion connected with the attachment body 82) of the support 84 serves as a load point. In other words, the support 84 is a continuously formed member having the effort point, the fulcrum, and the load point. Accordingly, the operator who installs the power source housing 60 can easily adjust a height position of the attachment body 82 connected to the load point by operating the height adjustment member 85 on one end side of the holding member 80.

The holding member 80 holds the power source housing 60 via the lower jig 90. The lower jig 90 is formed in an L-shape that holds corner portions of the power source housing 60 in the left-right direction and extends in a depth direction of the power source housing 60 in a front view of the power source housing 60. The lower jig 90 and the attachment body 82 of the holding member 80 are fixed to each other by threadedly engaging a fastening bolt 91 with the screw hole 824 (see FIG. 3) formed on one end side of the attachment body 82. That is, the operator can also connect the attachment body 82 and the lower jig 90 on the one end side of the holding member 80, and thus the power source housing 60 can be easily installed.

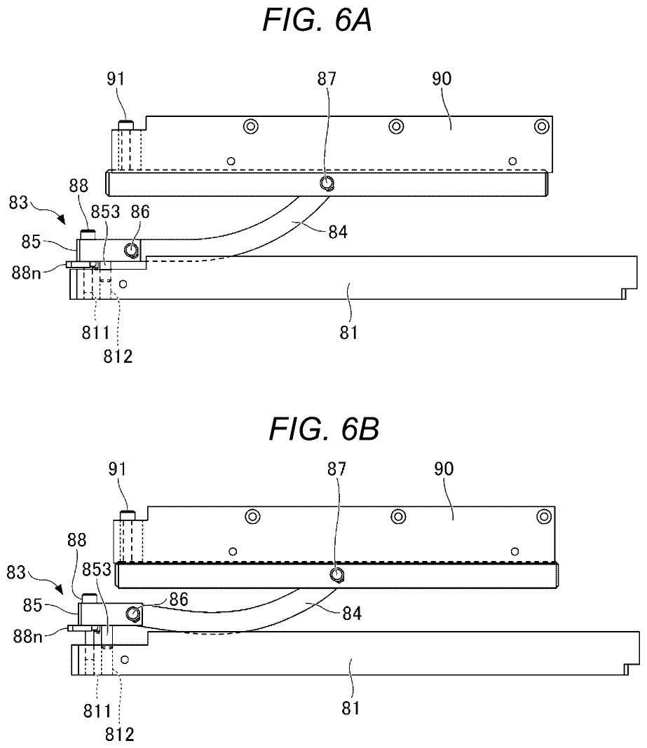

FIGS. 6A and 6B are side views illustrating adjustment of a height position of the holding member 80, FIG. 6A shows a state where the attachment body 82 is disposed at a high position, and FIG. 6B shows a state where the attachment body 82 is disposed at a low position. As shown in FIG. 6A, when the height position of the attachment body 82 that supports the lower jig 90 and the power source housing 60 (see FIG. 5) is set to be high, the height adjustment screw 88 is deeply engaged threadedly to the nut 88n or the base body 81. The height adjustment member 85 pressed by the height adjustment screw 88 is displaced to a low position as a whole. In other words, the height adjustment member 85 is positioned such that an interval between the base body 81 and the base portion 851 of the height adjustment member 85 is narrow. Accordingly, the one end of the support 84 connected to the height adjustment member 85 is also pushed down to the low position.

The support 84 whose one end side is pushed down by the height adjustment member 85 extends substantially linearly from the one end (effort point) to a predetermined range, and forms a fulcrum (support range) when this portion comes into contact with the base body 81. A curved portion of the support 84 extends at a relatively steep angle away from the fulcrum, and thus the attachment body 82 connected to the other end (load point) can be disposed at a high position.

On the other hand, as shown in FIG. 6B, when the height position of the attachment body 82 is set to be low, the height adjustment screw 88 is threadedly engaged loosely with respect to the nut 88n or the base body 81. The height adjustment member 85 pressed by the height adjustment screw 88 is displaced to a high position as a whole. In other words, the height adjustment member 85 is positioned such that the interval between the base body 81 and the base portion 851 of the height adjustment member 85 is wide. Accordingly, the one end of the support 84 connected to the height adjustment member 85 is also pushed up to the high position.

The support 84 whose one end side is pushed up by the height adjustment member 85 extends from the one end (effort point) while being slightly curved downward. Then, a curved extension portion of the support 84 comes into contact with the base body 81 to form the fulcrum (support range). At this time, the fulcrum of the support 84 is moved more in the depth direction than the fulcrum of the support 84 in FIG. 6A. In the support 84, a length of the curved portion from the fulcrum to the attachment body 82 to which the other end (load point) is connected is short, and thus the attachment body 82 can be disposed at a low position.

In this way, the holding member 80 can easily adjust, by the height adjustment member 85 and the height adjustment screw 88 on the one end side, the height position of the attachment body 82 supported by the support 84. Accordingly, the holding member 80 can absorb a machine-specific variation, an assembly error, and the like of the power source housing 60, and can dispose the power source housing 60 at an appropriate position in the accommodation space 50s.

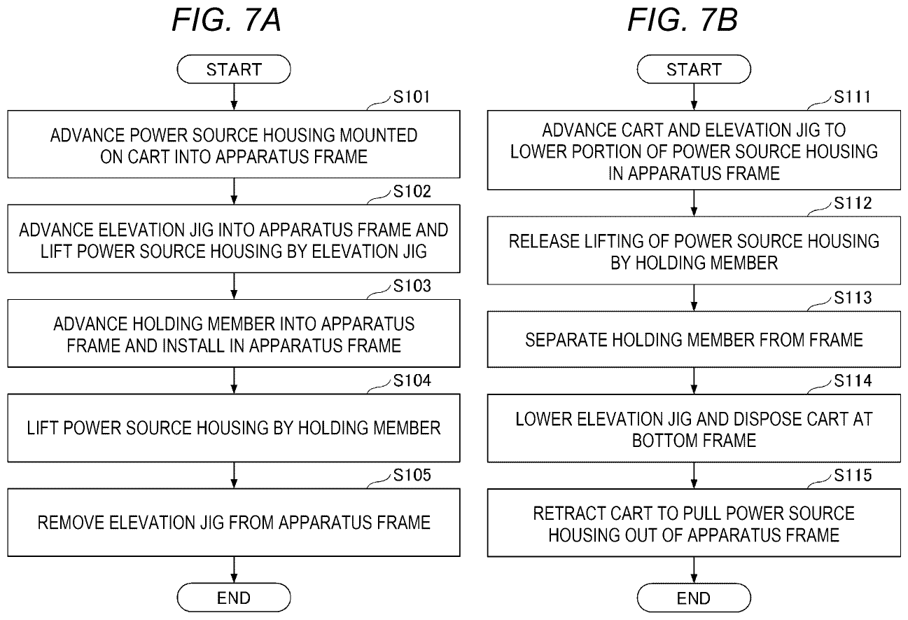

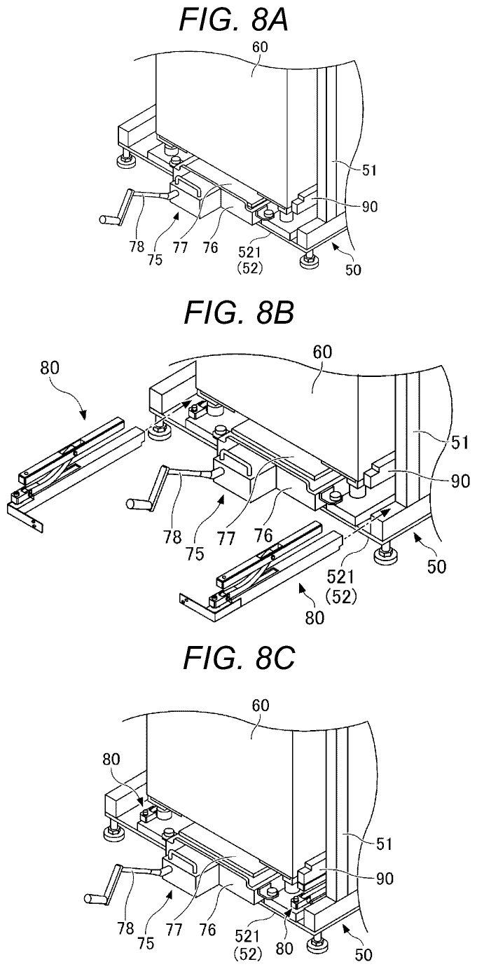

The semiconductor production apparatus (plasma processing apparatus 1) according to the embodiment is basically implemented as described above, and an installation method for installing the power source housing 60 to the apparatus frame 50 will be described below. FIG. 7A is a flowchart illustrating a procedure of the installation method for installing the power source housing 60 to the apparatus frame 50. FIG. 7B is a flowchart illustrating a procedure of a removing method for removing the power source housing 60 from the apparatus frame 50. FIG. 8A is a first perspective view illustrating a process when the power source housing 60 is installed. FIG. 8B is a second perspective view illustrating a process subsequent to FIG. 8A. FIG. 8C is a third perspective view illustrating a process subsequent to FIG. 8B.

As shown in FIG. 7A, in the installation method, first, the power source housing 60 is mounted on and integrated with the cart 70, and the power source housing 60 is advanced into the accommodation space 50s of the apparatus frame 50 together with the cart 70 (step S101). The lower jig 90 (see FIG. 5) may be attached to the power source housing 60 after the cart 70 is mounted, or the lower jig 90 may be attached to the power source housing 60 in advance before mounting of the cart 70. The cart 70 moves on the bottom frame 521 after climbing the inclined frame 55 of the apparatus frame 50, and advances into the accommodation space 50s. Accordingly, the operator can smoothly dispose the power source housing 60 in the accommodation space 50s.

Next, the operator advances the elevation jig 75 into the accommodation space 50s of the apparatus frame 50 and below the power source housing 60 supported by the cart 70, and further lifts the power source housing 60 by the elevation jig 75 (step S102). Specifically, as shown in FIG. 8A, the elevation jig 75 is inserted into a space between the bottom frame 521 and the panel stage 71 of the cart 70 from the opening of the accommodation space 50s. The elevation jig 75 is disposed at a substantially intermediate position in a width direction of the power source housing 60. Thereafter, the operator rotates the handle 78 of the elevation jig 75 to lift the stage 77, bring the stage 77 into contact with the panel stage 71 of the cart 70, and further continues lifting to lift the power source housing 60.

After the power source housing 60 is lifted by the elevation jig 75, the operator advances the pair of holding members 80 below the power source housing 60 in the accommodation space 50s, and installs the holding members 80 at the apparatus frame 50 (step S103). As shown in FIG. 8B, the operator aligns an extending direction of each holding member 80 from the opening of the accommodation space 50s toward the depth direction and linearly inserts each holding member 80. As shown in FIG. 5, a guide member 56 that guides an insertion direction of the holding member 80 and restricts movement of the holding member 80 in the depth direction is fixed to the upper surface of the bottom frame 521 of the apparatus frame 50. When the holding member 80 advances in the depth direction, the positioning portion 815 obtained by cutting away a lower portion of the other end is caught on the guide member 56. Accordingly, the holding member 80 is positioned with respect to the bottom frame 521.

Thereafter, the operator lifts the attachment body 82 from the base body 81 to fix the lower jig 90 of the power source housing 60 and the attachment body 82, and further lifts the power source housing 60 from the elevation jig 75 by threadedly engaging the height adjustment screw 88 of the height adjustment member 85 (step S104). As shown in FIG. 8C, when the pair of holding members 80 lift the power source housing 60, the power source housing 60 is held only by the holding members 80.

As shown in FIG. 2A, the power source housing 60 may be fixed to the apparatus frame 50 by a fixing member 58 in a state of being held by the pair of holding members 80. FIG. 2A shows a state where the sub-housing 62 and the intermediate frame 522 are fixed by the fixing member 58. However, a fixing unit between the apparatus frame 50 and the power source housing 60 is not limited thereto, and for example, the main housing 61 and the apparatus frame 50 (the side frames 51 or the like) may be connected.

Finally, the operator removes the elevation jig 75 from the apparatus frame 50, detaches the cart 70 from the lower portion of the power source housing 60 lifted by the pair of holding members 80, and retracts the cart 70 from the apparatus frame 50 (step S105 in FIG. 7A). Accordingly, the operator can efficiently establish a state where the power source housing 60 and the holding members 80 are accommodated in the accommodation space 50s of the apparatus frame 50.

In apparatus maintenance or the like, the power source housing 60 is removed from the apparatus frame 50 to perform inspection, repair, replacement, and the like for the plasma processing apparatus 1. As for a method for removing the power source housing 60 from the apparatus frame 50, the power source housing 60 can be easily removed by performing a procedure reverse to the installation method as shown in FIG. 7B.

Specifically, the operator first advances the cart 70 and the elevation jig 75 to the lower portion of the power source housing 60 lifted by the pair of holding members 80 in the apparatus frame 50, and supports the power source housing 60 by the stage 77 of the elevation jig 75 (step S111).

Then, the operator operates the height adjustment screw 88 on the one end side (the opening side of the accommodation space 50s) of the holding member 80 to release the state of lifting the power source housing 60 by the holding members 80 (step S112). At this time, the operator releases fixation of the attachment body 82 and the lower jig 90, and loosens threading engagement of the height adjustment screw 88. Accordingly, each holding member 80 is smoothly lowered with respect to the lower jig 90 of the power source housing 60.

Thereafter, the operator detaches the pair of holding members 80 from the apparatus frame 50 (step S113). That is, each holding member 80 is detachably accommodated in the power source housing 60 in a state where the power source housing 60 is located inside the apparatus frame 50, and thus can be removed at a timing different from that of the power source housing 60.

Then, the operator lowers the stage 77 by operating the handle 78 of the elevation jig 75 to bring the caster 72 of the cart 70 where the power source housing 60 is mounted into contact with the bottom frame 521 (step S114). The operator further lowers the stage 77 to separate the elevation jig 75 from the cart 70, and thus the elevation jig 75 can be removed. Accordingly, the operator detaches the elevation jig 75 from the apparatus frame 50.

Finally, the operator retracts the cart 70 to pull out the power source housing 60 from the apparatus frame 50 (step S115). Through this removing method, the operator can smoothly remove the power source housing 60 from the apparatus frame 50.

As described above, using the holding members 80, the plasma processing apparatus 1 can easily position and fix the power source housing 60 that is an accommodated object accommodated in the apparatus frame 50. Accordingly, the plasma processing apparatus 1 can improve work efficiency of installing and removing the power source housing 60 with respect to the inside of the apparatus frame 50 by the operator. In particular, the plasma processing apparatus 1 can stably hold the power source housing 60 in the apparatus frame 50 by holding the power source housing 60 by the pair of holding members 80.

By lifting the power source housing 60 based on the leverage principle using the holding member 80, the operator can perform an operation on the one end side of the holding member 80, and thus an operation on a back side of the apparatus frame 50 can be avoided. Further, by implementing the leverage principle by the continuous support member 84, the holding member 80 can improve strength for holding the power source housing 60. In particular, since the support 84 has a curved shape in the vicinity of a fulcrum portion, the strength can be further improved. By controlling threading engagement of the height adjustment screw 88 of the height adjustment member 85, the operator can easily adjust the height of the attachment body 82.

The technique of the present disclosure is not limited to the embodiment described above, and various modifications may be made. For example, the accommodated object accommodated inside the apparatus frame 50 is not limited to the power source housing 60, and can be various configurations of the semiconductor production apparatus. In this case as well, using the holding members 80 for each configuration of the semiconductor production apparatus, the configuration can be installed in a lifted state.

The semiconductor production apparatus is not limited to the plasma processing apparatus 1 described above, and can also be, for example, various apparatuses that perform substrate processing such as film formation, etching, cleaning, temperature adjustment, bonding, and peeling, an apparatus that performs inspection of the substrate W, and an apparatus that transfers the substrate W.

The holding members 80 accommodated in the apparatus frame 50 are not limited to one pair, and may be one or three or more. For example, when one holding member 80 is used, the base body 81, the attachment body 82, and the support 84 may be widened in a width direction, and the number of the base body 81, the attachment body 82, and the support 84 may be increased.

The embodiments disclosed above include, for example, the following aspects.

### Appendix 1

A semiconductor production apparatus for producing a semiconductor, the semiconductor production apparatus including:
an accommodated object installed inside an apparatus frame of the semiconductor production apparatus; and
a holding member accommodated inside the apparatus frame together with the accommodated object and configured to hold the accommodated object, in which
the holding member includes a base body, an attachment body attached to a lower portion of the accommodated object, and a lifting structure provided between the base body and the attachment body to lift the attachment body from the base body.

### Appendix 2

The semiconductor production apparatus according to Appendix 1, in which
the lifting structure comprises a support having a contact portion that contacts the base body to serve as a fulcrum for lifting the attachment body.

### Appendix 3

The semiconductor production apparatus according to Appendix 1, in which
the lifting structure includes a continuously formed support having an effort point, a fulcrum supported by the base body, and a load point connected to the attachment body.

### Appendix 4

The semiconductor production apparatus according to Appendix 3, in which
the lifting structure includes a height adjuster connected to the effort point of the support and configured to adjust a height of the effort point.

### Appendix 5

The semiconductor production apparatus according to Appendix 4, in which
the height adjuster includes, at an end opposite to a connection location connected to the support, a height adjustment screw threadedly engaged with the base body.

### Appendix 6

The semiconductor production apparatus according to any one of Appendices 3 to 5, in which
the support extends in a curved manner from the effort point toward the load point.

### Appendix 7

The semiconductor production apparatus according to any one of Appendices 3 to 6, in which
the support is rotatably connected to the attachment body at the load point.

### Appendix 8

The semiconductor production apparatus according to any one of Appendices 1 to 7, in which
the holding member is attachable to and detachable from the accommodated object in a state where the accommodated object is located inside the apparatus frame.

### Appendix 9

The semiconductor production apparatus according to Appendix 8, in which
the holding member includes a positioning portion that is positioned in the apparatus frame by sliding relatively with respect to the apparatus frame.

### Appendix 10

The semiconductor production apparatus according to any one of Appendices 1 to 9, in which
a pair of the holding members are disposed at the lower portion of the accommodated object.

### Appendix 11

The semiconductor production apparatus according to any one of Appendices 1 to 10, in which
the accommodated object is a power source housing accommodating a power source that is applied to the semiconductor production apparatus.

### Appendix 12

The semiconductor production apparatus according to Appendix 1, further comprising a lower jig attached to the accommodated object, wherein
the attachment body of the holding member is fixed to the lower jig.

### Appendix 13

The semiconductor production apparatus according to Appendix 1, further comprising a guide member fixed to a bottom frame of the apparatus frame, wherein
the holding member includes a positioning portion configured to be positioned by catching on the guide member when sliding in a depth direction.

### Appendix 14

The semiconductor production apparatus according to Appendix 3, wherein
the base body includes a guide groove that supports the lifting structure at a fulcrum between the effort point and the load point, and
a lower surface of the support contacts a bottom surface of the guide groove to define the fulcrum.

### Appendix 15

An installation method for installing an accommodated object in a semiconductor production apparatus for producing a semiconductor, the installation method including:
(A) accommodating the accommodated object inside an apparatus frame of the semiconductor production apparatus;
(B) accommodating a holding member inside the apparatus frame at a lower portion of the accommodated object after (A); and
(C) operating a lifting structure provided between a base body of the holding member and an attachment body attached to the lower portion of the accommodated object to lift the attachment body with respect to the base body after (B).

### Appendix 16

The installation method according to Appendix 15, further comprising:
before (A), attaching a lower jig to a lower portion of the accommodated object, wherein in (C), the attachment body is lifted into engagement with the lower jig to hold the accommodated object.

### Appendix 17

The installation method according to Appendix 15, further comprising:
between (A) and (B), lifting the accommodated object within the apparatus frame using an elevation jig inserted between a bottom frame of the apparatus frame and a cart supporting the accommodated object.

### Appendix 18

The installation method according to Appendix 15, wherein
in (B), the holding member is slid into the apparatus frame from an opening of the apparatus frame in a depth direction until a positioning portion of the holding member engages a guide member fixed to a bottom frame of the apparatus frame.

### Appendix 19

The installation method according to Appendix 15, further comprising: after (C), removing the elevation jig from the apparatus frame and retracting a cart supporting the accommodated object from the apparatus frame.

### Appendix 20

A method for removing an accommodated object from a semiconductor production apparatus, the method comprising:
(A) supporting the accommodated object, which is held inside an apparatus frame of the semiconductor production apparatus by a holding member, with an elevation jig;
(B) operating a lifting structure provided between a base body of the holding member and an attachment body attached to a lower portion of the accommodated object to lower the attachment body with respect to the base body;
(C) removing the holding member from the apparatus frame; and
(D) retracting the accommodated object from the apparatus frame using a cart.

The semiconductor production apparatus and the installation method according to the embodiment disclosed herein are illustrative and are not limited in all aspects. Various modifications and improvements can be made to the embodiments without departing from the spirit and scope of the appended claims. The aspects disclosed in the above embodiments also can have the other configurations to the extent not conflict, and can be combined with each other to the extent not conflict.

The substrate processing apparatus according to the present disclosure can be applied to an atomic layer deposition (ALD) apparatus and an apparatus of any type including capacitively coupled plasma (CCP), inductively coupled plasma (ICP), radial line slot antenna (RLSA), electron cyclotron resonance plasma (ECR), and helicon wave plasma (HWP).

1. A semiconductor production apparatus for producing a semiconductor, the semiconductor production apparatus comprising:
an accommodated object installed inside an apparatus frame of the semiconductor production apparatus; and
a holding member accommodated inside the apparatus frame together with the accommodated object and configured to hold the accommodated object, the holding member including:
a base body;
an attachment body attached to a lower portion of the accommodated object; and
a lifting structure provided between the base body and the attachment body to lift the attachment body from the base body.

2. The semiconductor production apparatus according to claim 1, wherein
the lifting structure comprises a support having a contact portion that contacts the base body to serve as a fulcrum for lifting the attachment body.

3. The semiconductor production apparatus according to claim 1, wherein
the lifting structure includes a continuously formed support having an effort point, a fulcrum supported by the base body, and a load point connected to the attachment body.

4. The semiconductor production apparatus according to claim 3, wherein
the lifting structure includes a height adjuster connected to the effort point of the support and configured to adjust a height of the effort point.

5. The semiconductor production apparatus according to claim 4, wherein
the height adjuster includes, at an end opposite to a connection location connected to the support, a height adjustment screw threadedly engaged with the base body.

6. The semiconductor production apparatus according to claim 3, wherein the support extends in a curved manner from the effort point toward the load point.

7. The semiconductor production apparatus according to claim 3, wherein the support is rotatably connected to the attachment body at the load point.

8. The semiconductor production apparatus according to claim 1, wherein
the holding member is attachable to and detachable from the accommodated object in a state where the accommodated object is located inside the apparatus frame.

9. The semiconductor production apparatus according to claim 8, wherein
the holding member includes a positioning portion that is positioned in the apparatus frame by sliding relatively with respect to the apparatus frame.

10. The semiconductor production apparatus according to claim 1, wherein
a pair of the holding members are disposed at the lower portion of the accommodated object.

11. The semiconductor production apparatus according to claim 1, wherein
the accommodated object is a power source housing accommodating a power source that is applied to the semiconductor production apparatus.

12. The semiconductor production apparatus according to claim 1, further comprising a lower jig attached to the accommodated object, wherein
the attachment body of the holding member is fixed to the lower jig.

13. The semiconductor production apparatus according to claim 1, further comprising a guide member fixed to a bottom frame of the apparatus frame, wherein
the holding member includes a positioning portion configured to be positioned by catching on the guide member when sliding in a depth direction.

14. The semiconductor production apparatus according to claim 3, wherein
the base body includes a guide groove that supports the lifting structure at a fulcrum between the effort point and the load point, and
a lower surface of the support contacts a bottom surface of the guide groove to define the fulcrum.

15. An installation method for installing an accommodated object in a semiconductor production apparatus for producing a semiconductor, the installation method comprising:
(A) accommodating the accommodated object inside an apparatus frame of the semiconductor production apparatus;
(B) accommodating a holding member inside the apparatus frame at a lower portion of the accommodated object after (A); and
(C) operating a lifting structure provided between a base body of the holding member and an attachment body attached to the lower portion of the accommodated object to lift the attachment body with respect to the base body after (B).

16. The installation method according to claim 15, further comprising:
before (A), attaching a lower jig to a lower portion of the accommodated object, wherein in (C), the attachment body is lifted into engagement with the lower jig to hold the accommodated object.

17. The installation method according to claim 15, further comprising:
between (A) and (B), lifting the accommodated object within the apparatus frame using an elevation jig inserted between a bottom frame of the apparatus frame and a cart supporting the accommodated object.

18. The installation method according to claim 15, wherein
in (B), the holding member is slid into the apparatus frame from an opening of the apparatus frame in a depth direction until a positioning portion of the holding member engages a guide member fixed to a bottom frame of the apparatus frame.

19. The installation method according to claim 15, further comprising:
after (C), removing the elevation jig from the apparatus frame and retracting a cart supporting the accommodated object from the apparatus frame.

20. A method for removing an accommodated object from a semiconductor production apparatus, the method comprising:
(A) supporting the accommodated object, which is held inside an apparatus frame of the semiconductor production apparatus by a holding member, with an elevation jig;
(B) operating a lifting structure provided between a base body of the holding member and an attachment body attached to a lower portion of the accommodated object to lower the attachment body with respect to the base body;
(C) removing the holding member from the apparatus frame; and
(D) retracting the accommodated object from the apparatus frame using a cart.
